(19) United States
(12) Patent Application Publication
(10) Pub. No.: US 2006/0151850 A1
(43) Pub. Date: Jul. 13, 2006

(54) Method of Forming A Power Amplifier

(76) Inventors: Liang-Kuang Wei, Hsin-Chu Hsien (TW); Chih-Min Chiang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/907,102

(22) Filed: Mar. 21, 2005

(30) Foreign Application Priority Data
Jan. 13, 2005 (TW) 094100997

(51) Int. Cl. H01L 21/336; H01L 29/00

(52) U.S. Cl. 257/499; 438/301

(57) ABSTRACT

In a bipolar junction transistor (BJT) process, according to the linearity of an implant dosage and the output characteristics of a power amplifier, the implant dosage in the poly-silicon layer is selected and controlled in order to form different power level silicon germanium (SiGe) based power amplifiers. Cost, complexity, and time of IC manufacture are reduced.

### BACKGROUND OF INVENTION

1. Field of the Invention

The present invention relates to a method of forming a power amplifier, and more particularly, to a method of forming a power amplifier in a semiconductor process by selecting and controlling an implant dosage of a poly-silicon layer in the power amplifier.

2. Description of the Prior Art

As wireless technology grows rapidly, more and more semiconductor processes are developed for producing wireless integrated circuits (ICs). The silicon germanium (SiGe) technique is a new technique that is widely used by many wireless IC companies. The efficiency of a wireless product, such as an IEEE wireless LAN, wireless phone, or other device relates to the power amplifier in the wireless IC. By controlling the output power (or current consumption) with keeping other key amplifier characteristics acceptable, more high-power and low-current applications can be achieved.

In semiconductors, to change the output power of a power amplifier, the prior art requires changing the circuit design, which means the corresponding masks of the circuit design must be changed as well. In other words, to produce different power level ICs, the prior art must have lots of mask options, however, manufacturing additional sets of masks not only increases the overall cost, but also requires more time and thus delays the schedule, and so is not an economical solution.

### SUMMARY OF INVENTION

It is therefore an objective of the claimed invention to provide a simpler, lower-cost and more efficient method of forming different power level amplifiers in order to solve the problems of the prior art.

The present invention provides a method of forming a power amplifier in a 0.35 μm semiconductor process. The method comprises forming a poly-silicon layer, and implanting a dopant, whose implant dosage ranges from 4.6×10¹⁵ atoms/cm³ to 6.4×10¹⁵ atoms/cm³ or from 6.8×10¹⁵ atoms/cm³ to 7.3×10¹⁵ atoms/cm³, in the poly-silicon layer.

The present invention further provides a method of forming a power amplifier in a 0.18 μm semiconductor process, the method comprises forming a poly-silicon layer, and implanting a dopant, whose implant dosage ranges from 3.8×10¹⁵ atoms/cm³ to 5.3×10¹⁵ atoms/cm³ or from 5.7×10¹⁵ atoms/cm³ to 6.1×10¹⁵ atoms/cm³, in the poly-silicon layer.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a diagram of a silicon germanium technique used in a bipolar junction transistor process.

FIG. 2 is a diagram showing a correlation between the implant dosage and current consumption of a power amplifier.

FIG. 3 is a diagram showing a correlation between the implant dosage and output power of a power amplifier.

FIG. 4 is a flowchart showing the procedures of forming a power amplifier in a bipolar junction transistor process using a silicon germanium technique in the present invention.

### DETAILED DESCRIPTION

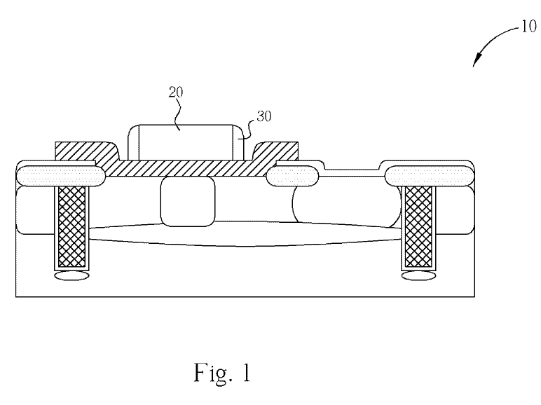

Please refer to FIG. 1, which shows a diagram of a silicon germanium technique used in a bipolar junction transistor process. After forming a poly-silicon layer 20 on a wafer 10, a step of implantation begins. Generally, an element will not be directly used during the implantation, but a compound of the element will. The compound of the element, which can be in a solid, liquid, or gaseous state, is usually transported by a diffusion source for implantation. For example, to implant phosphorous, POCl₃ can be the material, which is kept as in liquid state in a specific container. After oxygen and nitrogen gas are blown through the container, atoms of phosphorous are brought out by the gas and then deposited on the surface of the wafer 10. The atoms of phosphorous further react with the poly-silicon layer 20 to form a layer of silicon oxide comprising silicon, oxygen, and phosphorous. Thereafter, the atoms of phosphorous diffuse into the poly-silicon layer 20 as dopant. After the implantation step, a spacer 30 is formed to surround a sidewall of the poly-silicon layer 20. Then, following the semiconductor process, a bipolar junction transistor is formed on the wafer 10. Generally, the dopant in a 0.35 μm semiconductor process is phosphorous, whose standard dosage is 6.6×10¹⁵ atoms/cm³, and the dopant in a 0.18 μm semiconductor process is arsenic, whose standard dosage is 5.5×10¹⁵ atoms/cm³. These are the standards in the semiconductor industry, and IC designers and companies follow these standards to design their IC. However, according to the present invention, the implant dosage of the poly-silicon layer 20 is strongly correlated to current consumption and output power of a silicon germanium based power amplifier. By selecting and controlling the implant dosage of the poly-silicon layer 20 during the step of implantation, the present invention can be applied to build a power amplifier with expected output power or current consumption, and further manufacture the designed power level IC.

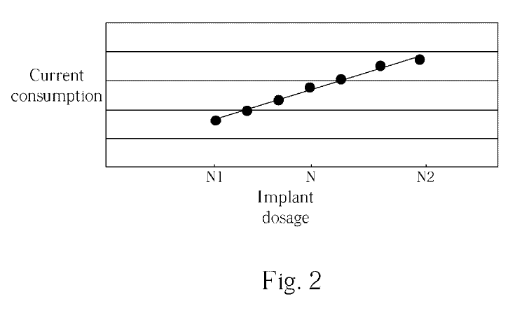

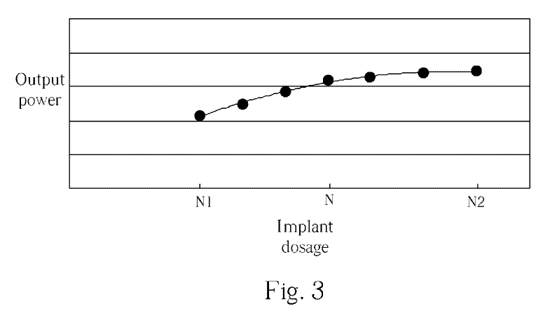

To further illustrate the method of the present invention, please refer to FIG. 2 and FIG. 3 (and refer to FIG. 1 as well). FIG. 2 is a diagram showing a correlation between the implant dosage and current consumption of a power amplifier. The horizontal axis of FIG. 2 represents the implant dosage, and the vertical axis of FIG. 2 represents current consumption of a power amplifier. FIG. 3 is a diagram showing a correlation between the implant dosage and output power of a power amplifier. The horizontal axis of FIG. 3 represents the implant dosage, and the vertical axis of FIG. 3 represents output power of a power amplifier. According to the present invention, as shown in FIG. 2 and FIG. 3, in the bipolar junction transistor process using the silicon germanium technique, the implant dosage of the poly-silicon layer 20 is proportional to current consumption and output power of a silicon germanium based power amplifier. Moreover, the above correlation has good linearity near the standard dosage N, for example, from implant dosage N1 to implant dosage N2. In other words, to increase current consumption or output power of a power amplifier, the present invention can increase the implant dosage of the poly-silicon layer according to the linear correlation. Similarly, to decrease current consumption or output power of a power amplifier, the present invention can decrease the implant dosage of the poly-silicon layer according to the linear correlation.

In addition, the implant dosage and dopant in the 0.35 μm semiconductor process are different from the implant dosage and dopant in the 0.18 μm semiconductor process. As to the 0.35 μm semiconductor process, the dopant is phosphorous, whose implant dosage ranges from 4.6×10¹⁵ atoms/cm³ to 7.3×10¹⁵ atoms/cm³. In this range, the phosphorous implant dosage of the poly-silicon layer 20 is linearly proportional to current consumption and output power of a silicon germanium based power amplifier. On the other hand, as to the 0.18 μm semiconductor process, the dopant is arsenic, whose implant dosage ranges from 3.8×10¹⁵ atoms/cm³ to 6.1×10¹⁵ atoms/cm³. In this range, the arsenic implant dosage of the poly-silicon layer 20 is linearly proportional to current consumption and output power of a silicon germanium based power amplifier. For example, when the present invention is to increase output power of a silicon germanium based power amplifier in the 0.35 μm semiconductor process, according to the above linear correlation, the phosphorous implant dosage of the poly-silicon layer 20 is increased in order to increase output power. Similarly, when the present invention is to decrease current consumption of a silicon germanium based power amplifier in the 0.18 μm semiconductor process, according to the above linear correlation, the arsenic implant dosage of the poly-silicon layer 20 is decreased in order to decrease current consumption. In the above two examples, the present invention does not need a change in the original circuit design, but only requires selection and control of the implant dosage of the poly-silicon layer 20 according to the linear correlation between the implant dosage and output characteristics (current consumption and output power) of a power amplifier.

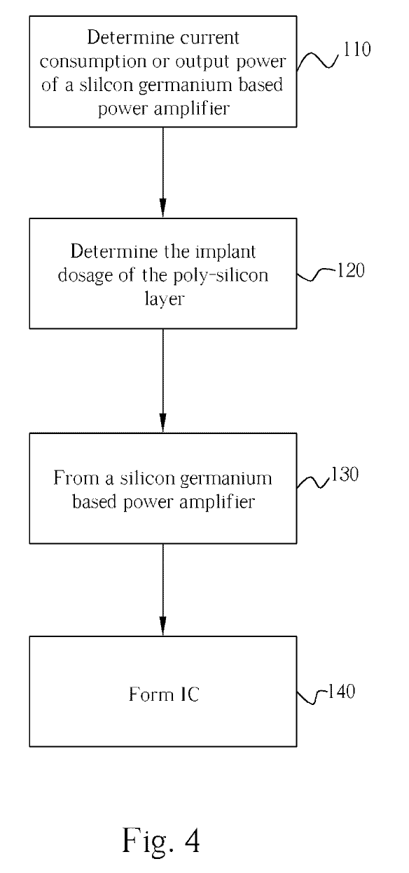

Summarizing the above, the procedures of forming a power amplifier in a bipolar junction transistor process using the silicon germanium technique in the present invention can be described with the flowchart of FIG. 4. Please refer to FIG. 4; the flowchart comprises the following steps:

Step 110: Determine current consumption or output power of a silicon germanium based power amplifier. To change current consumption or output power of a silicon germanium based power amplifier without modifying the original circuit design, the present invention first determines current consumption or output power of the silicon germanium based power amplifier according to the above method.

Step 120: Determine the implant dosage of the poly-silicon layer 20. According to the linear correlation between the implant dosage and current consumption or output power of a silicon germanium based power amplifier, the present invention is used to find the corresponding implant dosage of the expected current consumption or output power, and control the implant dosage of the poly-silicon layer during the implantation step in the semiconductor process.

Step 130: Form the designed silicon germanium based power amplifier. After completing the above implantation, the remaining standard semiconductor processes are continued to form the designed silicon germanium based power amplifier.

Step 140: Form the IC. After completing all the semiconductor processes, the expected power level IC is manufactured.

Overall, according to the above method of forming a power amplifier, the present invention can be applied to a bipolar junction transistor process using the silicon germanium technique. Moreover, based on different semiconductor processes, such as the current 0.35 μm semiconductor process and the 0.18 μm semiconductor process, different dopants are used in the poly-silicon layer 20, and the implant dosage is selected and controlled in a specified range, which is outside the standard dosage. For example, in the 0.35 μm semiconductor process, the dopant is phosphorous, whose implant dosage ranges from 4.6×10¹⁵ atoms/cm³to 6.4×10¹⁵ atoms/cm³ or from 6.8×10¹⁵ atoms/cm³ to 7.3×10¹⁵ atoms/cm³ in the poly-silicon layer 20; in the 0.18 μm semiconductor process, the dopant is arsenic, whose implant dosage ranges from 3.8×10¹⁵ atoms/cm³to 5.3×10¹⁵ atoms/cm³ or from 5.7×10¹⁵ atoms/cm³ to 6.1×10¹⁵ atoms/cm³ in the poly-silicon layer 20. According to the method of the present invention, the implant dosage of the poly-silicon layer 20 can be selected and controlled to be in the specified range, in order to form a power amplifier with the expected output characteristics and further build the designed power level IC.

In contrast to the prior art, the present invention simply selects and controls the implant dosage of the poly-silicon layer according to the linear correlation between the implant dosage and output characteristics of a power amplifier, in order to form different power level amplifiers without changing the original circuit design. Therefore, the present invention not only reduces cost, complexity, and time during manufacturing ICs, but also increases the efficiency to push the products into the market.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power amplifier formed in a 0.35 μm semiconductor process, the power amplifier comprising:
a poly-silicon layer implanted with a dopant, whose implant dosage ranges from 4.6×10¹⁵ atoms/cm³ to 6.4×10¹⁵ atoms/cm³ or from 6.8×10¹⁵ atoms/cm³ to 7.3×10¹⁵ atoms/cm³; and
a spacer surrounding a sidewall of the poly-silicon layer.

2. The power amplifier of claim 1 wherein the semiconductor process is a bipolar junction transistor process.

3. The power amplifier of claim 1 being a silicon germanium based power amplifier.

4. The power amplifier of claim 1 wherein the dopant is phosphorous.

5. A power amplifier formed in a 0.18 μm semiconductor process, the power amplifier comprising:
a poly-silicon layer implanted with a dopant, whose implant dosage ranges from 3.8×10¹⁵ atoms/cm³ to 5.3×10¹⁵ atoms/cm³ or from 5.7×10¹⁵ atoms/cm³ to 6.1×10¹⁵ atoms/cm³; and
a spacer surrounding a sidewall of the poly-silicon layer.

6. The power amplifier of claim 5 wherein the semiconductor process is a bipolar junction transistor process.

7. The power amplifier of claim 5 being a silicon germanium based power amplifier.

8. The power amplifier of claim 1 wherein the dopant is arsenic.

9. A method of forming a power amplifier in a 0.35 μm semiconductor process, the method comprising the following steps:
(a) forming a poly-silicon layer; and
(b) implanting a dopant, whose implant dosage ranges from 4.6×10¹⁵ atoms/cm³ to 6.4×10¹⁵ atoms/cm³ or from 6.8×10¹⁵ atoms/cm³ to 7.3×10¹⁵ atoms/cm³, in the poly-silicon layer.

10. The method of claim 9 wherein the semiconductor process is a bipolar junction transistor process.

11. The method of claim 9 wherein the power amplifier is a silicon germanium based power amplifier.

12. The method of claim 9 wherein step (b) comprises implanting atoms of phosphorous, whose implant dosage ranges from 4.6×10¹⁵ atoms/cm³ to 6.4×10¹⁵ atoms/cm³ or from 6.8×10¹⁵ atoms/cm³ to 7.3×10¹⁵ atoms/cm³, in the poly-silicon layer.

13. A method of forming a power amplifier in a 0.18 μm semiconductor process, the method comprising the following steps:
(a) forming a poly-silicon layer; and
(b) implanting a dopant, whose implant dosage ranges from 3.8×10¹⁵ atoms/cm³ to 5.3×10¹⁵ atoms/cm³ or from 5.7×10¹⁵ atoms/cm³ to 6.1×10¹⁵ atoms/cm³, in the poly-silicon layer.

14. The method of claim 13 wherein the semiconductor process is a bipolar junction transistor process.

15. The method of claim 13 wherein the power amplifier is a silicon germanium based power amplifier.

16. The method of claim 13 wherein step (b) comprises implanting atoms of arsenic, whose implant dosage ranges from 3.8×10¹⁵ atoms/cm³ to 5.3×10¹⁵ atoms/cm³ or from 5.7×10¹⁵ atoms/cm³ to 6.1×10¹⁵ atoms/cm³, in the poly-silicon layer.
